(19) United States
(12) Patent Application Publication
(10) Pub. No.: US 2023/0274669 A1
(43) Pub. Date: Aug. 31, 2023

(54) DISPLAY PANEL AND DISPLAY DEVICE

(71) Applicants: Changsha HKC Optoelectronics Co., Ltd., Changsha City (CN); HKC CORPORATION LIMITED, Shenzhen (CN)

(72) Inventors: Shengcai FAN, Changsha City (CN); Baohong KANG, Changsha City (CN)

(73) Assignees: Changsha HKC Optoelectronics Co., Ltd., Changsha City (CN); HKC CORPORATION LIMITED, Shenzhen (CN)

(21) Appl. No.: 18/092,098

(22) Filed: Dec. 30, 2022

(30) Foreign Application Priority Data
Feb. 28, 2022 (CN) 202210187124.X

(51) Int. Cl. G09F 9/30; G09F 9/302; H05K 1/18

(52) U.S. Cl. CPC G09F 9/301; G09F 9/3026; H05K 1/18; H05K 2201/09036; H05K 2201/10128

(57) ABSTRACT

The present disclosure relates to the field of display devices, and provides a display panel including a plurality of panels spliced to each other, in which the spliced panel includes a back panel, a display body mounted on a first face of the back panel, and a printed circuit board mounted on a second face of the back panel, in which the display body is electrically connected to the printed circuit board and includes a display part and a substrate; and the spliced panel further includes a flexible substrate, in which one end of the flexible substrate is electrically connected to a display body, and the other end of the flexible substrate is electrically connected to a back face of a printed circuit board.

### CROSS-REFERENCE TO RELATED APPLICATIONS

This present application claims priority under 35 U.S.C. § 119 to Chinese patent application No. 202210187124.X filed on Feb. 28, 2022 before the China National Intellectual Property Administration of the People's Republic of China, the contents of which is explicitly incorporated herein by reference in its entirety.

### FIELD

The present disclosure relates to the technical field of splicing screens, particularly to a display panel and a display device.

### BACKGROUND

A display device comprises a display panel mounted within a housing; since there are only small-size display panels currently, a large-size display panel needs to be formed by splicing a plurality of small-size spliced panels;
the spliced panel generally comprises a back panel, a display body mounted on a side of the back panel, and a printed circuit board mounted on the other side of the back panel; the display body is electrically connected to the printed circuit board.

In the related art, a line connecting the display body and the printed circuit board needs to pass through a seam between two adjacent spliced panels; a bend radius of the line in the related art is too large, which causes the seam between the two spliced panels to be too wide, thereby affecting a display effect of the display device.

### SUMMARY

The present disclosure aims to provide a display panel comprising a flexible substrate, wherein one end of the flexible substrate is electrically connected to the display body; the other end of the flexible substrate is electrically connected to a back face of a printed circuit board; as compared to the related art, a bend radius of the flexible substrate of the present disclosure is reduced, and therefore the size of the seam between the spliced panels is reduced, thereby improving a display effect of the display panel.

In a first aspect, the present disclosure provides a display panel comprising a plurality of panels spliced to each other, the spliced panel comprising a back panel, a display body mounted on a first face of the back panel, and a printed circuit board mounted on a second face of the back panel, wherein the display body is electrically connected to the printed circuit board and comprises a display part and a substrate; the spliced panel further comprising a flexible substrate, wherein one end of the flexible substrate is electrically connected to the display body, the other end of the flexible substrate is electrically connected to a back face of the printed circuit board.

In a second aspect. the present disclosure further provides a display device comprising a housing and the display panel mounted on the housing.

According to the display panel and the display device provided by embodiments of the present disclosure have the following advantages, the display panel comprises a plurality of splicing panels spliced to each other, wherein the splicing panel comprises a back panel, a display body mounted on a first face of the back panel, and a printed circuit board mounted on a second face of the back panel; the display body comprises a display part and a substrate; the splicing panel further comprises a flexible substrate, wherein one end of the flexible substrate is electrically connected to the display body; the other end of the flexible substrate is electrically connected to a back face of a printed circuit board; as compared to the related art, a bend radius of the flexible substrate of the present disclosure is reduced, and therefore the size of the seam between the splicing panels is reduced, thereby contributing to improving a display effect of the display device using the display panel.

### BRIEF DESCRIPTION OF THE DRAWINGS

The accompanying drawings here, which are incorporated in and constitute a part of the specification, show embodiments according to the disclosure and serve to explain principles of the disclosure together with the specification.

In order to more clearly illustrate technical solutions in the embodiments or the related art, the drawings that need to be used in description of the embodiments or the related art are briefly introduced below, and it will be apparent to those of ordinary skill in the art that other drawings may be obtained based on these drawings without inventive work.

FIG. 1 is a schematic diagram of a structure of a display panel according to a first embodiment of the present disclosure;

FIG. 2 is a schematic diagram illustrating a mounting means of a flexible substrate of the display panel according to a first embodiment of the present disclosure;

FIG. 3 is a perspective view of a structure after mounting of the flexible substrate of the display panel according to a first embodiment of the present disclosure;

FIG. 4 is a schematic diagram of a structure of a display panel according to a second embodiment of the present disclosure; and

FIG. 5 is a schematic diagram of a structure of a display device according to a third embodiment of the present disclosure.

### DESCRIPTION OF REFERENCE NUMERALS

100: display body;
101: substrate; 102: display part; 1021: wiring groove; 103: connection line;
200: protection layer;
300: flexible substrate; 3001: first connection part;
400: back panel;
500: adhesive layer;
600: printed circuit board; 601: back face;
700: seam;
800: housing;
900: display panel;
x: first direction.

### DETAILED DESCRIPTION

In order to make objects, technical solutions, and advantages of embodiments of the disclosure clearer, the technical solutions in the embodiments of the disclosure will be clearly and fully described in combination with the accompanying drawings in the embodiments of the present disclosure. Obviously, the embodiments to be described are part of embodiments but not all embodiments of the disclosure. Based on the embodiments in the disclosure, all other embodiments obtained by those of ordinary skill in the art without inventive work shall fall within the scope of the disclosure.

### First Embodiment

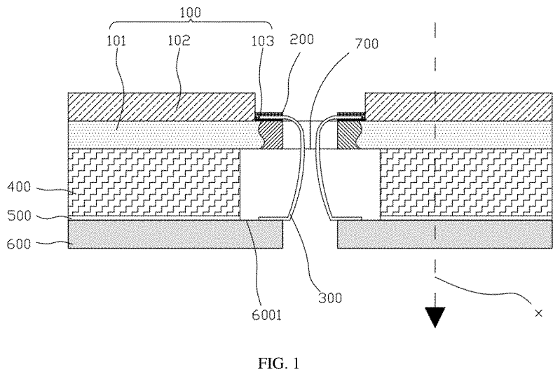

Referring to FIGS. 1 to 3, an embodiment of the present disclosure provides a display panel comprising a plurality of panels spliced to each other, wherein the spliced panel comprises a back panel 400, a display body 100 mounted on a first face of the back panel 400, and a printed circuit board 600 mounted on a second face of the back panel 400; the display body 100 is electrically connected to the printed circuit board 600; the display body 100 comprises a display part 102 and a substrate 101, and the printed circuit board 600 and the back panel 400 are connected via an adhesive layer 500.

In the display panel provided by an embodiment of the present disclosure, one end of the flexible substrate 300 is electrically connected to the display part 102, and the other end of the flexible substrate 300 is electrically connected to the printed circuit board 600.

In the above example, further, the flexible substrate 300 is electrically connected to a back face 601 of the printed circuit board 600; the design described above may also reduce a bend radius of the flexible substrate 300, which contributes to reducing a size of a seam 700 and increasing a display effect of the display panel.

In some examples, in the display panel, the substrate 101 is provided with a wiring channel via which the flexible substrate 300 electrically connects the display part 102 with the printed circuit board 600, thereby solving problems in the related art that a line passes through the seam 700, causing the seam 700 to be too wide and the line is damaged due to extrusion of the two adjacent spliced panels. In some examples, a projection of the substrate 101 in a first direction x covers a projection of other components of the spliced panel in the first direction x; the seam 700 is located at a location between the substrate 101 of one spliced panel and the substrate 101 of another adjacent spliced panel.

In some examples, the wiring channel is a wiring groove 1021 disposed on a side of the substrate 101; in this embodiment, a line connecting the display body 100 with the printed circuit board 600 passes through the wiring groove 1021;

Regarding the disposition of the wiring groove 1021, on one hand, the line does not need to pass through the seam 700 between the spliced panels, thereby avoiding affecting the width of the seam 700, and is not damaged by the extrusion of the two adjacent spliced panels; on the other hand, the line is arranged on the wiring groove 1021 provided on the side of the substrate 101, a process of which is simpler than that of a hole.

In some embodiments, a plurality of first connection parts 3001 are protruded from one side of the flexible substrate 300, the side of the substrate 101 is provided with a plurality of the wiring grooves 1021 in one-to-one correspondence with a plurality of the first connection parts 3001; and the first connection part 3001 is electrically connected to the display part 102 through the corresponding wiring groove 1021.

In the design described above, the flexible substrate 300 is not a conventional “rectangular” shape, and a bend radius of the flexible substrate 300 of the design described above is smaller than that of a flexible substrate 300 of a “rectangular” shape, thereby reducing the width of the seam 700.

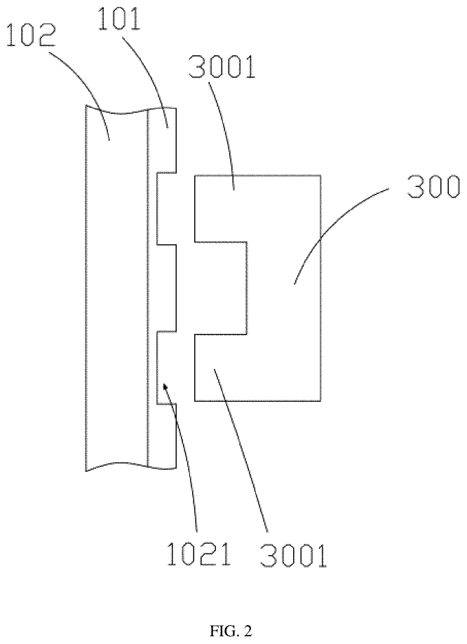

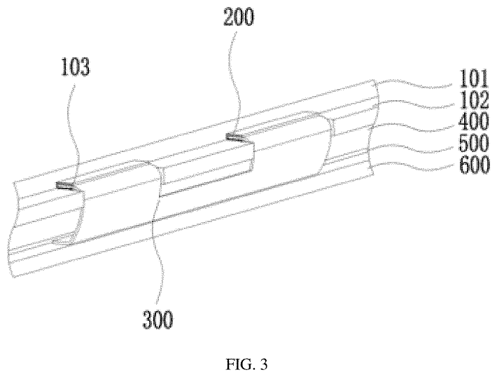

In the above examples, the flexible substrate 300 has a “U” shape, in particular referring to FIGS. 2 and 3, two first connection parts 3001 are protruded from one side of the flexible substrate 300, the side of the substrate 101 is provided with two wiring grooves 1021 in one-to-one correspondence with the two first connection parts 3001; and the two first connection part 3001 are electrically connected to the display part 102 through the wiring grooves 1021 respectively.

In the above examples, the flexible substrate 300 passes through the wiring groove 1021 so as not to occupy space of the seam 700, and is not subject to extrusion of the two adjacent spliced panels, thereby avoiding damage by the extrusion.

The flexible substrate 300 passes through the wiring groove 1021 and is not exposed to the edge, which can reduce the risk of folding of the flexible substrate 300 during the splicing process.

In the above examples, the flexible substrate 300 has a “U” shape, is less elastic (properties due to shape), and therefore has a smaller bend radius than a rectangular flexible substrate in the related art, so that the width of the seam 700 and the depth of the wiring groove 1021 can be reduced.

In the above examples, further, the substrate 101 is provided with a connection line 103, which may be a copper wire or an aluminum wire; the connection line 103 connects the display part 102 with the flexible substrate 300 to electrically connect the display part 102 with the flexible substrate 300.

In some examples, the substrate 101 is provided with a connection line 103; a first end of the connection line 103 is electrically connected to the display part 102; the other end of the connection line 103 is electrically connected to one end of the flexible substrate 300; and the other end of the flexible substrate 300 is electrically connected to the printed circuit board 600 through the wiring groove 1021.

In some examples, in order to protect the connection line 103, the surface of the connection line 103 is provided with a protection layer 200. The protection layer 200 is made of elastic material.

In the above examples, further, the protection layer 200 may be a heat curable glue, a moisture curable glue, a photocuring glue with elasticity; the protection layer 200 may also be made of other elastic materials in the related art.

In some examples, the side of the substrate 101 may also be provided with the protection layer 200; since the protection layer 200 is elastic, certain deformation space is imparted to the splicing structure after the panels are spliced.

In some examples, the display part 102 may be a micro LED display device, a sub-millimeter LED display device, a QLED display device, or an OLED display device. In some embodiments, the display part 102 may be the micro LED display device and comprises a light emitting unit which is a micro LED light emitting unit.

In some examples, the substrate 101 may be a flexible substrate or a hard substrate; the flexible substrate is preferably polyimide, and the hard substrate is preferably a silicide.

In some embodiments, the flexible substrate 300 may be a chip-on-film or non-chip-on-film flexible circuit board.

### Second Embodiment

In an embodiment of the present disclosure, the display panel comprises a plurality of panels spliced to each other, wherein the spliced panel comprises a back panel 400, a display body 100 mounted on a first face of the back panel 400, and a printed circuit board 600 mounted on a second face of the back panel 400; the display body 100 is electrically connected to the printed circuit board 600; the display body 100 comprises a display part 102 and a substrate 101. In an embodiment of the present disclosure, a projection of the substrate 101 in a first direction x covers a projection of other components of the spliced panel in the first direction x; the seam 700 is located at a location between the substrate 101 of one spliced panel and the substrate 101 of another adjacent spliced panel.

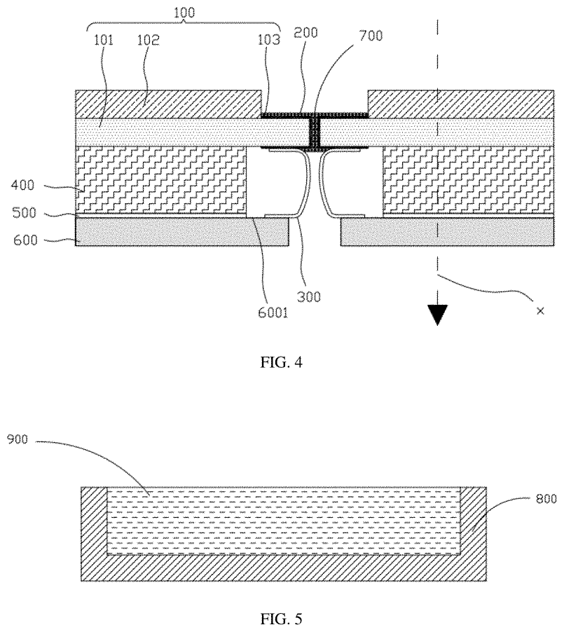

Referring to FIG. 4, in an embodiment of the present disclosure, the substrate 101 of the display body 100 is provided with a connection line 103; a first end of the connection line 103 is electrically connected to the display part 102; a second end of the connection line 103 extends to a face of the substrate 101 opposite to the display part 102; one end of the flexible substrate 300 is electrically connected to the connection line 103; and the other end of the flexible substrate 300 is electrically connected to the printed circuit board 600.

Referring to FIG. 4, in an embodiment of the present disclosure, the display body 100 is electrically connected to the printed circuit board 600 in the manner described above; in an embodiment of the present disclosure, the printed circuit board 600 does not pass through the seam 700, and therefore does not affect the width of the seam 700 and is not damaged by extrusion and friction of the two adjacent spliced panels.

In some examples, one end of the flexible substrate 300 is electrically connected to the display part 102, and the other end of the flexible substrate 300 is electrically connected to the printed circuit board 600.

In the above examples, further, the flexible substrate 300 is electrically connected to a back face 601 of the printed circuit board 600; the design described above may also reduce a bend radius of the flexible substrate 300.

In some examples, in order to protect the connection line 103, the surface of the connection line 103 is provided with a protection layer 200. The protection layer 200 is made of elastic material.

In the above examples, further, the protection layer 200 may be a heat curable glue, a moisture curable glue, a photocuring glue with elasticity; the protection layer 200 may also be made of other elastic materials in the related art.

In some examples, the side of the substrate 101 may also be provided with the protection layer 200; since the protection layer 200 is elastic, certain deformation space is imparted to the splicing structure after the panels are spliced.

In some examples, the side of the substrate 101 is provided with a wiring groove 1021 through which the connection line 103 passes; this design protects the connection line 103.

In the above examples, further, the protection layer 200 on the side of the substrate 101 may be coated with a light-reflective layer; so that the seam 700 can reflect light, thereby avoiding a dark line at the seam 700 and improving the display effect.

In the above examples, further, the protection layer 200 on the side of the substrate 101 may be coated with a light-reflective layer; so that the seam 700 can reflect light, thereby avoiding a dark line at the seam 700 and improving the display effect.

In some examples, the display part 102 may be a micro LED display device, a sub-millimeter LED display device, a QLED display device, or an OLED display device. In some embodiments, the display part 102 may be the micro LED display device and comprises a light emitting unit which is a micro LED light emitting unit.

In some examples, the substrate 101 may be a flexible substrate or a hard substrate; the flexible substrate is preferably polyimide, and the hard substrate is preferably a silicide.

In some examples, the flexible substrate 300 may be a chip-on-film or non-chip-on-film flexible circuit board.

### Third Embodiment

An embodiment of the present disclosure provides a display device comprising a housing 800; and
a display panel 900 which is the display panel of the first embodiment or the second embodiment and is mounted on the housing 800. It should be understood that the display device further comprises other necessary elements which belong to the related art, so details thereof are not described here.

Due to the above design of the substrate 101 of the display panel 900, a line connecting the display part 102 of the display panel 900 with the printed circuit board 600 does not need to pass through the seam 700; in particular, the flexible substrate 300 does not need to pass through the seam 700; this effectively reduces the width of the seam 700, thereby improving the display effect of the display device.

Meanwhile, in the display panel 900, the surface of the connection line 103 is covered with a protection layer 200, and the protection layer 200 protects the connection line 103.

Meanwhile, the side of the substrate of the display panel 900 may also be provided with the protection layer 200; since the protection layer 200 is elastic, certain deformation space is imparted to the splicing structure after the panels are spliced. The protection layer 200 on the side of the substrate 101 may be coated with a light-reflective layer; so that the seam 700 can reflect light, thereby avoiding a dark line at the seam 700 and improving the display effect.

It should be noted that relationship terms such as “first” and “second” are used solely for distinguishing one entity or operation from another entity or operation herein without necessarily requiring or implying any actual relationship or order among the entities or operations. Furthermore, the terms “comprise”, “comprising”, or any other variants thereof are intended to encompass non-exclusive inclusion, so that a process, method, article, or device comprising a series of elements not only comprises those elements but also comprises other elements not expressly listed or elements inherent to such a process, method, article or device. Without more limitation, an element defined by a phrase “comprise a . . . ” does not exclude the presence of additional identical elements in the process, method, article or device that comprises the elements.

The above is only detailed description of the disclosure to enable those skilled in the art to understand or implement the disclosure. Various modifications to these embodiments will be apparent to those skilled in the art, and the general principles defined herein may be implemented in other embodiments without departing from the spirit or scope of the disclosure. Thus, the present disclosure is not limited to the embodiments illustrated herein, but shall conform to the widest scope consistent with the principles and novelty applied herein.

What is claimed is:

1. A display panel comprising a plurality of panels spliced to each other, the spliced panel comprising a back panel, a display body mounted on a first face of the back panel, and a printed circuit board mounted on a second face of the back panel, wherein the display body is electrically connected to the printed circuit board and comprises a display part and a substrate; the spliced panel further comprising a flexible substrate, wherein one end of the flexible substrate is electrically connected to the display body, the other end of the flexible substrate is electrically connected to a back face of the printed circuit board.

2. The display panel of claim 1, wherein the substrate is provided with a wiring channel; and the flexible substrate electrically connects the display part with the printed circuit board through the wiring channel.

3. The display panel of claim 2, wherein the wiring channel is a wiring groove provided on a side of the substrate.

4. The display panel of claim 3, wherein the substrate is provided with a connection line; a first end of the connection line is electrically connected to the display part; the other end of the connection line is electrically connected to one end of the flexible substrate; and the other end of the flexible substrate is electrically connected to the printed circuit board through the wiring groove.

5. The display panel of claim 4, wherein a plurality of first connection parts are protruded from one side of the flexible substrate, the side of the substrate is provided with a plurality of the wiring grooves in one-to-one correspondence with a plurality of the first connection parts; and the first connection part is electrically connected to the display part through the corresponding wiring groove.

6. The display panel of claim 1, wherein the substrate is provided with a connection line; a first end of the connection line is electrically connected to the display part; a second end of the connection line extends to a face of the substrate opposite to the display part; one end of the flexible substrate is electrically connected to the connection line; and the other end of the flexible substrate is electrically connected to the printed circuit board.

7. The display panel of claim 6, wherein a side of the substrate is provided with a wiring groove through which the connection line passes.

8. The display panel of claim 4, wherein the surface of the connection line is covered with a protection layer, and the protection layer is made of elastic materials.

9. The display panel of claim 8, wherein the side of the substrate is further provided with the protection layer.

10. The display panel of claim 8, wherein the protection layer is a heat curable glue, a moisture curable glue or a photocuring glue with elasticity.

11. The display panel of claim 10, wherein the protection layer on the side of the substrate is coated with a light-reflective layer.

12. The display panel of claim 6, wherein the surface of the connection line is covered with a protection layer, and the protection layer is made of elastic materials.

13. The display panel of claim 12, wherein the side of the substrate is further provided with the protection layer.

14. The display panel of claim 12, wherein the protection layer is a heat curable glue, a moisture curable glue or a photocuring glue with elasticity.

15. The display panel of claim 14, wherein the protection layer on the side of the substrate is coated with a light-reflective layer.

16. The display panel of claim, wherein the display body comprises a plurality of light emitting units.

17. The display panel of claim 16, wherein the display part is a micro LED display device, a sub-millimeter LED display device, a QLED display device, or an OLED display device.

18. The display panel of claim 17, wherein the display part is the micro LED display device, and the light emitting unit is a micro LED light emitting unit.

19. A display device comprising a housing; and
a display panel mounted on the housing, the display panel comprising a plurality of panels spliced to each other, the spliced panel comprising a back panel, a display body mounted on a first face of the back panel, and a printed circuit board mounted on a second face of the back panel, wherein the display body is electrically connected to the printed circuit board and comprises a display part and a substrate; the spliced panel further comprising a flexible substrate, wherein one end of the flexible substrate is electrically connected to the display body, the other end of the flexible substrate is electrically connected to a back face of the printed circuit board.
